(19) United States
(12) Patent Application Publication
(10) Pub. No.: US 2022/0232809 A1
(43) Pub. Date: Jul. 28, 2022

(54) COMPUTER AQUARIUM MOUNTING STRUCTURE

(71) Applicant: EDAC ELECTRONICS TECHNOLOGY (HANGZHOU) CO., LTD, Hangzhou (CN)

(72) Inventor: HUANTANG LIN, Hangzhou (CN)

(21) Appl. No.: 17/189,453

(22) Filed: Mar. 2, 2021

(30) Foreign Application Priority Data
Jan. 28, 2021 (CN) 202120239587.7

(51) Int. Cl. A01K 63/00; H05K 7/20; G06F 1/20

(52) U.S. Cl. CPC A01K 63/006; G06F 2200/201; G06F 1/20; H05K 7/20236

(57) ABSTRACT

A computer aquarium mounting structure includes an aquarium with water, wherein, a through hole is provided on the side wall of the aquarium, a motor case is installed on the outer wall of the aquarium, a computer motherboard is provided inside the motor case, a radiator is provided inside the aquarium, and the radiator is sealingly provided at the through hole, a CPU and/or a graphics card installed on the computer motherboard contact with the outside of the radiator. The disclosure can combine the aquarium with the computer organically, which can not only cool the computer through the aquarium, but also create a real sense of the desktop natural landscape. Moreover, it doesn't take up more space on the desktop, and doesn't make any noise because a fan will not be needed.

### CROSS-REFERENCE TO RELATED APPLICATIONS

This is a U.S. patent application which claims the priority and benefit of Chinese patent application number 202120239587.7, filed on Jan. 28, 2021, the disclosure of which is incorporated herein by reference in its entirety.

### TECHNICAL FIELD

The disclosure relates to the field of computer cooling, in particular to a computer aquarium mounting structure.

### BACKGROUND

The aquarium screen saver is very popular, the computer desktop and aquarium have in common with ornamental. But the aquarium screen saver is a virtual technology. The eyes will be tired after using the computer screen for a long time, so people usually get up to watch the natural scenery outside the window. The aquarium is a closer indoor natural scenery, so the aquarium screen saver appears to meet the needs of computer users. However, but the aquarium screen saver is not a natural scenery, and lacks of a real eye care function.

### SUMMARY

The purpose of the disclosure is to provide a computer aquarium mounting structure, which is intended to solve the problems raised in the background of the invention.

The embodiment of the disclosure is implemented in this way, a computer aquarium mounting structure includes an aquarium with water, wherein, a through hole is provided on the side wall of the aquarium, a motor case is installed on the outer wall of the aquarium, a computer motherboard is provided inside the motor case, a radiator is provided inside the aquarium, and the radiator is sealingly provided at the through hole, a CPU and/or a graphics card installed on the computer motherboard contact with the outside of the radiator.

Further, the CPU and/or the graphics card contact with the outside of the radiator through a lining plate or a filling structure.

As a result of the above-mentioned technical solution, the disclosure can combine the aquarium with the computer organically, which can not only cool the computer through the aquarium, but also create a real sense of the desktop natural landscape. Moreover, it doesn't take up more space on the desktop, and doesn't make any noise because a fan will not be needed.

### BRIEF DESCRIPTION OF DRAWINGS

FIG. 1 shows a three-dimensional diagram of the disclosure.

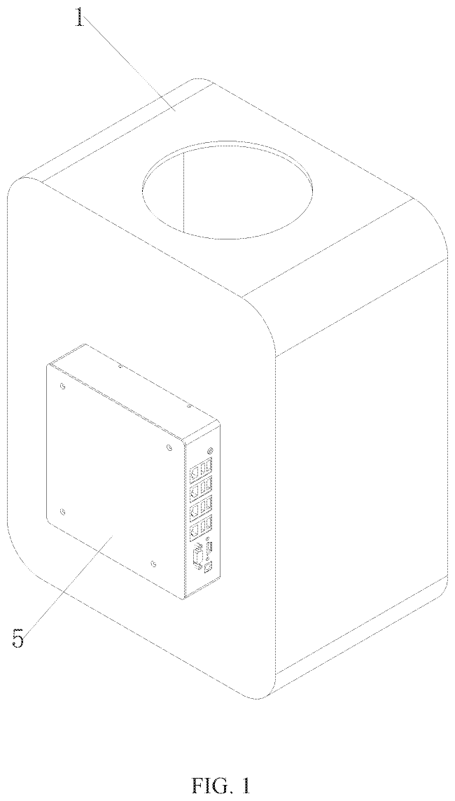

FIG. 2 shows a section view of the disclosure.

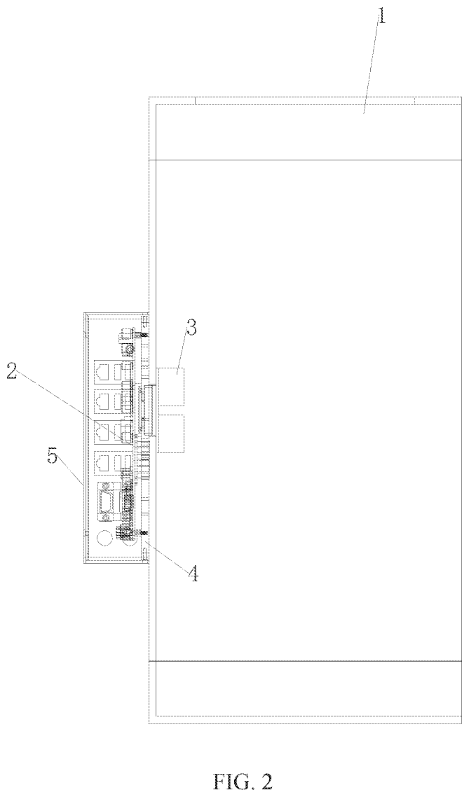

FIG. 3 shows a diagram of an aquarium.

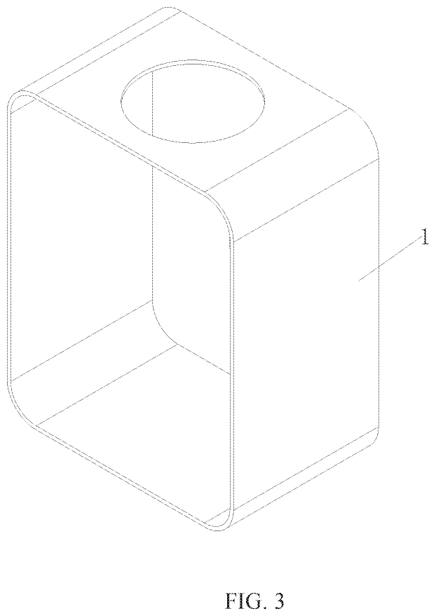

In the drawings:

| | |
|---|---|
| 1. Aquarium | 2. Computer motherboard |
| 3. Radiator | 4. filling structure |
| 5. Motor case | |

### DETAILED DESCRIPTION

In order to make the purpose, technical solution and advantages of the disclosure more clearly, the disclosure, combined with drawings and embodiments, will be further detailed. It should be understood that the specific embodiments described herein are intended only to explain the disclosure and are not intended to qualify the disclosure.

In addition, in the description of the application, the terminology used should be understood in a broad sense, and for the technical staff in the field, the specific meaning of the term may be understood in the context of the actual circumstances. For example, the terms “provide” and “arrange” used in this application may be defined as contact settings or contactless settings, etc., and the azimuth terms used are based on reference sits or in the direction defined by the actual situation and common sense.

As an aspect of the disclosure, a computer aquarium mounting structure includes: an aquarium 1 with water, a through hole is provided on the side wall of the aquarium 1, a motor case 5 is installed on the outer wall of the aquarium 1, a computer motherboard 2 is provided inside the motor case 5, a radiator 3 is provided inside the aquarium 1, and the radiator 3 is sealingly provided at the through hole, a CPU and/or a graphics card installed on the computer motherboard 2 contact with the outside of the radiator 3. Preferably, the CPU and/or the graphics card contact with the outside of the radiator through a lining plate or a filling structure 4.

In the above-mentioned technical solution, the through hole of the disclosure is provided on the back or side of the aquarium 1 according to the size of the radiator 3 shown above, to ensure that the cooling part of the radiator is mounted inside the aquarium, a heat guide surface of the radiator for contacting the CPU is fixed on the outer wall of the aquarium, and then is sealed to ensure that no water leaks. The CPU is reversely mounted on the computer motherboard 2, and is provided on the outer wall of the aquarium. And the CPU is tightly contacted with the radiator 3 through the lining or filling structure 4. In cases of expansion, the computer's stand-alone graphics card could also be installed in the same way as above.

Since the water or liquid in the aquarium has a fairly high thermal capacity, the heat from the CPU and/or graphics card is transmitted into the water through the radiator 3, and then is dissipated into the air by evaporation of water and heat transfer from the water surface of the aquarium wall, thus resulting in a greater cooling space. Therefore, the cooling fans used in conventional computers are no longer needed, and the noise is essentially eliminated. The radiator in the disclosure forms a single heat transmission channel between the computer and the aquarium, rather than make the water connected with the computer host, which is more secure and reliable than conventional water-cooled cooling. In addition, the computer desktop system integrated the aquarium with the computer provides a good using environment for computer users. For computer users who love aquariums, the waste heat of the computer and the corresponding temperature control device can also be used to improve the breeding conditions of aquariums. In the disclosure, the host assembly and the cooling liquid are divided into two completely isolated spaces, which is different from the usual meaning of the liquid cooling mode, without special requirements, such as conductivity etc., to the liquid itself, but with the clear advantages of suitability and cost.

As a result of the above-mentioned technical solution, the disclosure can combine the aquarium with the computer organically, which can not only cool the computer through the aquarium, but also create a real sense of the desktop natural landscape. Moreover, it doesn't take up more space on the desktop, and doesn't make any noise because a fan will not be needed. The greenness of the computer reaches a new level.

The disclosure adopts a non-active passive radiator, which does not require a fan, but only needs to simply maintain a certain area of thermal contact with the liquid.

The embodiments described above represent only a few embodiments of the disclosure, its description is more specific and detailed, but cannot be understood as a limitation on the scope of the patent of the disclosure. It should be pointed out that for ordinary technical personnel in the art, without departing from the concept of the disclosure, you can also make a number of deformations and improvements, these are the scope of protection of the disclosure. Therefore, the scope of protection of the patent of the disclosure shall be subject to the attached claim.

What is claimed is:

1. A computer aquarium mounting structure comprising an aquarium with water, wherein, a through hole is provided on the side wall of the aquarium, a motor case is installed on the outer wall of the aquarium, a computer motherboard is provided inside the motor case, a radiator is provided inside the aquarium, and the radiator is sealingly provided at the through hole, a CPU and/or a graphics card installed on the computer motherboard contact with the outside of the radiator.

2. The computer aquarium mounting structure according to claim 1, wherein the CPU and/or the graphics card contact with the outside of the radiator through a lining plate or a filling structure.
